(19) United States
(12) Patent Application Publication
(10) Pub. No.: US 2025/0301812 A1
(43) Pub. Date: Sep. 25, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Jaio-Wei Wang, Kaohsiung City (TW); Min-Feng Kao, Chiayi City (TW); Ko Chun Liu, Miaoli County (TW); Meng-Hsien Lin, Tainan City (TW); Hsing-Chih Lin, Tainan City (TW)

(73) Assignee: Taiwan Semiconductor Manufacturing Company, Ltd., Hsinchu (TW)

(21) Appl. No.: 18/616,073

(22) Filed: Mar. 25, 2024

(51) Int. Cl. H01L 27/146

(52) U.S. Cl. CPC H10F 39/811; H10F 39/014; H10F 39/18

(57) ABSTRACT

A semiconductor device includes an integrated circuit. The integrated circuit includes a semiconductor substrate, an active device, an interconnect structure and a capacitor. The capacitor extends into the semiconductor substrate and the interconnect structure.

### BACKGROUND

Optical imaging devices such as digital cameras or mobile phone cameras employ image sensors. Image sensors convert optical images to digital data that may be represented as digital images. An image sensor typically includes an array of pixel sensors which absorb radiation and convert the sensed radiation into electrical signals. As the size of transistor devices shrinks with each technology generation, further improvements are needed for increased processing of the optical images and device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views of various stages in a method of forming a semiconductor device according to some embodiments.

FIG. 2 is a schematic cross-sectional view of a semiconductor device according to some embodiments.

FIG. 3 is a schematic cross-sectional view of a semiconductor device according to some embodiments.

FIG. 4 is a schematic cross-sectional view of a semiconductor device according to some embodiments.

FIG. 5 is a schematic cross-sectional view of a semiconductor device according to some embodiments.

FIG. 6 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Source/drain region(s) may refer to a source or a drain, individually or collectively, dependent upon the context.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

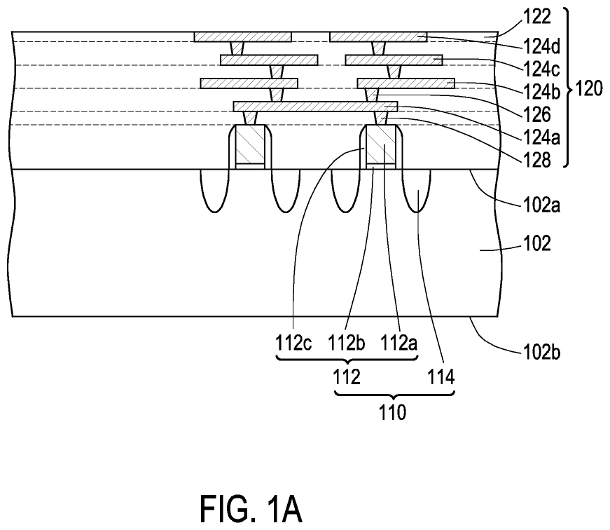

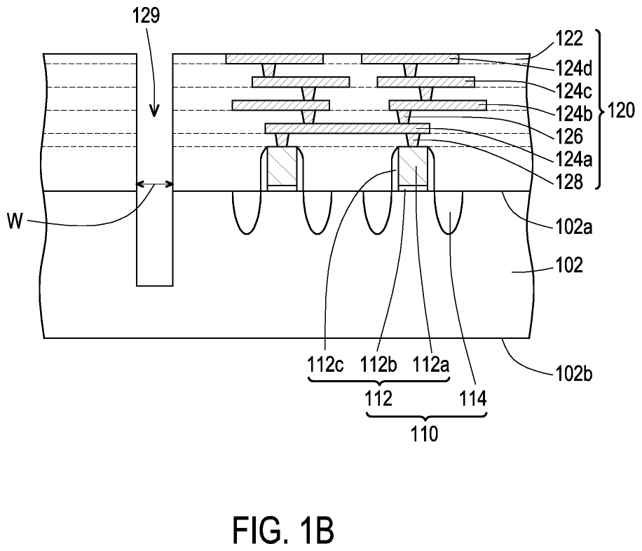

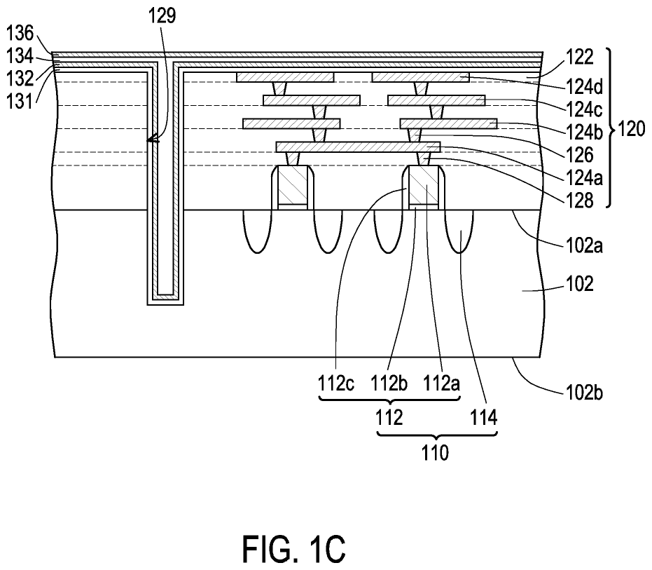

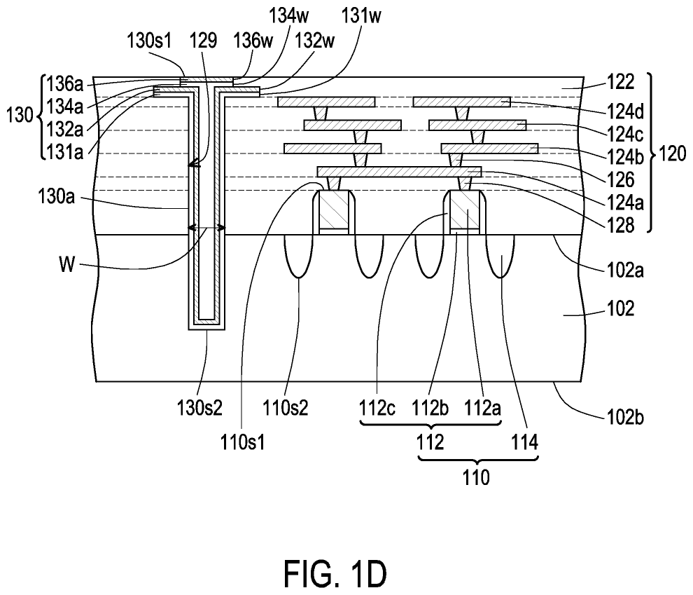

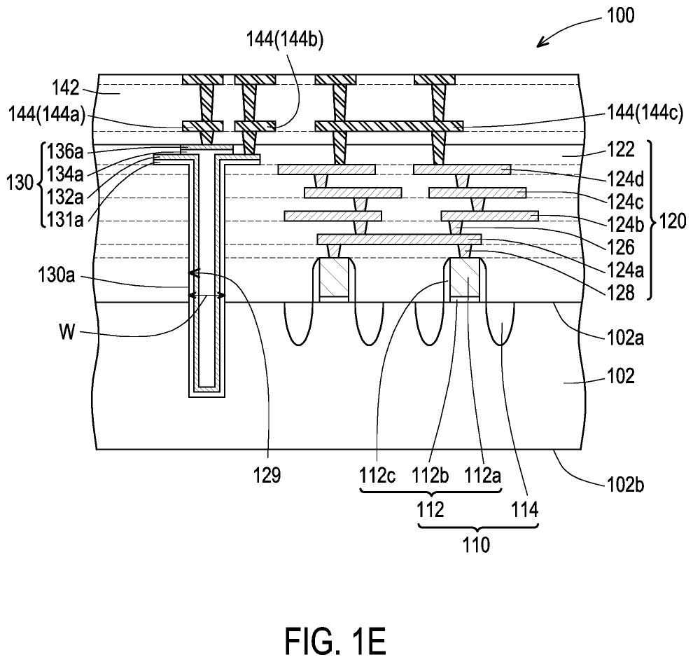

FIG. 1A to FIG. 1E are schematic cross-sectional views of various stages in a method of forming a semiconductor device according to some embodiments.

Referring to FIG. 1A, a semiconductor substrate 102 is provided. The semiconductor substrate 102 may be a substrate of doped or undoped silicon. In some embodiments, the semiconductor substrate 102 include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 102 has a first side (e.g., front side) 102a and a second side (e.g., a backside) 102b opposite to the first side 102a. The front side may also be referred to as device side. In some embodiments, the semiconductor substrate 102 is a wafer substrate.

The semiconductor substrate 102 may include electrical circuits 110 therein. In some embodiments, the electrical circuits 110 may include various n-type metal-oxide semiconductor (NMOS) and/or p-type metal-oxide semiconductor (PMOS) devices, such as transistors, capacitors, resistors, diodes, fuses, combinations thereof, and/or the like. The electrical circuits 110 may be interconnected to perform one or more functions, which may include memory structures, processing structures, sensors, amplifiers, power distribution, input/output circuitry and/or the like. In some embodiments, the electrical circuits 110 are transistors. For example, the electrical circuit 110 includes a gate structure 112 and source/drain regions 114 at opposite sides of the gate structure 112. The Each electrical circuit 110 may further include a channel region (not shown) under the gate structure 112. The channel region may be also located between the source/drain regions 114 to serve as a path for electron to travel when the electrical circuit 110 is turned on. In some embodiments, the electrical circuits 110 may be separated by shallow trench isolation (STI; not shown) located between two adjacent electrical circuits 110.

In some embodiments, the semiconductor substrate 102 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; combinations thereof; and/or the like. In some embodiments, these doped regions serve as the source/drain regions 114 of the electrical circuit 110. Depending on the types of the dopants in the doped regions, the electrical circuits 110 may be referred to as n-type transistors or p-type transistors.

In some embodiments, the gate structure 112 includes a gate electrode 112a, a gate dielectric layer 112b and spacers 112c. The gate electrode 112a may be a poly gate, a poly silicide gate, an amorphous gate, an amorphous silicide gate, a vertical transfer gate, doped poly gate, and any types of high-k metal gate. The gate electrode 112a may include copper, titanium, tantalum, tungsten, aluminum, zirconium, hafnium, cobalt, titanium aluminum, tantalum aluminum, tungsten aluminum, zirconium aluminum, hafnium aluminum, titanium nitride, combinations thereof, and/or the like. The gate dielectric layer 112b is disposed under the gate electrode 112a, and the spacers 112c are disposed on opposite sidewalls of the gate electrode 112a. In some embodiments, the gate structure 112 also includes a work function layer to fine-tune the corresponding work function. The work function layer may include p-type work function material such as Ru, Mo, WN, ZrSi₂, MoSi₂, TaSi₂, NiSi₂, combinations thereof, and/or the like, or n-type work function material such as Ag, TaCN, Mn, combinations thereof, and/or the like.

In some embodiments, as shown in FIG. 1A, the source/drain regions 114 are embedded in the semiconductor substrate 102 and the gate structure 112 is located above the semiconductor substrate 102. In some embodiments, the electrical circuits 110 are formed using suitable Front-end-of-line (FEOL) process. However, the disclosure is not limited thereto. In alternative embodiments, the source/drain regions 114 and the gate structure 112 are both located above the semiconductor substrate 102.

In alternative embodiments (not shown), a plurality of through vias are formed in the semiconductor substrate 102. The through via may be formed by a single damascene process. A via opening may be first formed in the semiconductor substrate 102 by, for example, etching, milling, laser techniques, the like, or combinations thereof. A thin barrier material may be conformally deposited in the via opening, such as by CVD, atomic layer deposition (ALD), physical vapor deposition (PVD), thermal oxidation, the like, or combinations thereof. The barrier material may be formed of an oxide, a nitride, a carbide, combinations thereof, or the like. A conductive material may be deposited over the barrier material and in the via opening. The conductive material may be formed by an electro-chemical plating process, CVD, ALD, PVD, the like, or combinations thereof. Examples of the conductive material are copper, tungsten, aluminum, silver, gold, the like, or combinations thereof. Excess conductive material and barrier material is removed from a surface of the semiconductor substrate 102 by, for example, a CMP. Remaining portions of the barrier material and conductive material form the through via.

Then, an interconnect structure 120 is formed over the first side 102a of the semiconductor substrate 102. The interconnect structure 120 may include a plurality of dielectric layers 122 and a plurality of interconnects 124a, 124b, 124c, 124d (collectively referred to as interconnects 124) therein. The dielectric layers 122 are formed over the semiconductor substrate 102. The interconnects 124 may be formed in and/or on the dielectric layers 122. The dielectric layers 122 and the interconnects 124 form a first back-end-of-line (BEOL) structure for the first integrated circuit 100. The interconnects 124 may be in the form of conductive lines/traces. Conductive features 126, such as conductive vias, are selectively provided between adjacent interconnects 124 to vertically interconnect the interconnects 124. In some embodiments, the conductive feature 126 has an inclined sidewall, and a width of the conductive feature 126 may decrease as the conductive feature 126 becomes away from the semiconductor substrate 102. The dielectric layers 122 and the interconnects 124 form first metallization layers over the semiconductor substrate 102. In alternative embodiments, the interconnects 124a are disposed at a first level in the dielectric layers 122 over the semiconductor substrate 102, the interconnects 124b are disposed at a second level over the first level, the interconnects 124c are disposed at a third level over the second level, and the interconnects 124d are disposed at a fourth level over the third level. In some embodiments, the interconnects 124a are disposed in a lower level (e.g., a level being adjacent the semiconductor substrate 102) in the dielectric layers 122 and the interconnects 124d are disposed in a higher level (e.g., a level being away from the semiconductor substrate 102) in the dielectric layers 122. In an embodiment, the interconnects 124d are top metallization layers disposed at the highest level in the dielectric layers 122.

In some embodiments, the interconnects 124a-c disposed at outer region of the dielectric layers 122 may serve as dummy metallization layers for blocking of moisture. The interconnects 124a-c disposed at inner region of the dielectric layers 122 are those metallization layers underneath the electrical circuits 110. Generally, metallization layers are used to interconnect the electrical circuitry to each other and to provide an external electrical connection. The electrical circuits 110 are in electrical connection with the interconnects 124 (e.g., interconnects 124a) through respective conductive contact 128 that is disposed between and in contact with the interconnect 124a and the gate electrode 112a of a transistor (e.g., electrical circuit 110). One skilled in the art will appreciate that number of stacked layers and the number/placement of the interconnects within the respective layers as shown in FIG. 1A are provided for illustration only and are not limiting the scope of the present disclosure. Other combinations of metallization layers forming a daisy chain or serial electrical coupling are also contemplated.

A material of the dielectric layers 122 may include a low-k dielectric material, such as phosphosilicate glass (PSG), borophosphosilicate glass (BPSG), FSG, SiOxCy, Spin-On-Glass, Spin-On-Polymers, silicon carbon material, compounds thereof, composites thereof, combinations thereof, and/or the like. The dielectric layers 122 may be formed by any suitable method, such as spin-on coating, chemical vapor deposition (CVD), plasma-enhanced CVD (PECVD), combinations thereof, and/or the like.

A material of the interconnects 124 may include conductive materials such as copper, aluminum, aluminum alloys, copper alloys or the like and may be formed by using any suitable formation process (e.g., lithography with etching, damascene, dual damascene, or the like). In some embodiments, the interconnects 124 may further include a diffusion barrier layer and/or an adhesion layer (not shown) to protect the first IMD layers from metal poisoning. The diffusion barrier layer may include one or more layers of TaN, Ta, TiN, Ti, CoW, or the like, and may be deposited by physical vapor deposition (PVD), or the like. Although not illustrated, one or more etch stop layers may be disposed between adjacent layers of the dielectric layers 122 and the semiconductor substrate 102, or between individual layers of the dielectric layers 122. The etch stop layers provide a mechanism to stop an etching process when forming vias and/or contacts. The etch stop layers are formed of a dielectric material having a different etch selectivity from adjacent layers, e.g., the underlying semiconductor substrate 102 and the overlying dielectric layers 122. In some embodiments, a material of the etch stop layers includes SiN, SiCN, SiOC, SiON, combinations thereof, and/or the like, and the etch stop layers are formed by a deposition process such as CVD or PECVD.

The interconnects 124a, 124b, 124c, 124d are electrically connected through the conductive features 126. The interconnects 124d are disposed at a level that is away from the electrical circuits 110 and may also be referred to as “Mx”. The interconnects 124c are disposed immediately adjacent the interconnects 124d and may also be referred to as “Mx-1.” The interconnects 124b are disposed immediately adjacent the interconnects 124c and may also be referred to as “Mx-2.” The interconnects 124a are disposed between the interconnects 124b and the electrical circuits 110 and may also be referred to as “Mx-3.” In some embodiments, the interconnects 124d (“Mx”) are top metallization layers disposed at a highest level in the IMD layers 122. In alternative embodiments (not shown), storage devices are disposed between adjacent two of the interconnects 124a, 124b, 124c, 124d. The storage devices may be any suitable capacitors or memory devices, such as metal-insulator-metal (MIM) capacitors or the like, which provide storage capacity for CMOS image sensors.

Referring to FIG. 1B, an opening 129 is formed in the dielectric layers 122 and a portion of the semiconductor substrate 102. For example, the opening 129 penetrates through the dielectric layers 122 and a portion of the semiconductor substrate 102. In some embodiments, the opening 129 is formed by using a photolithography process and an etching process. The etching process may include a first etching process to partially remove the dielectric layers 122 and a second etching process to partially remove the semiconductor substrate 102. The first etching process and the second etching process are respectively a dry etching process or a wet etching process. The first etching process may include an etchant as CF₄, a mix gas of C₄F₆ and O₂, combinations thereof and/or the like, and the second etching process may include an etchant as SF₆, C₄F₈, combinations thereof and/or the like. In some embodiments, the opening 129 has a vertical sidewall or a substantially vertical sidewall, and a width W of the opening 129 is substantially constant. However, the disclosure is not limited thereto. The opening 129 may include an inclined sidewall.

Referring to FIG. 1C, a first electrode material 132, a dielectric material 134 and a second electrode material 136 are sequentially formed on the opening 129 and the dielectric layers 122. For example, an isolation material 131 is conformally formed over an exposed top surface of the topmost dielectric layer 122 and exposed bottom and sidewall surfaces of the opening 129. Then, the first electrode material 132 may be conformally formed over the isolation material 131, and the dielectric material 134 may be formed over the first electrode material 132 and in the opening 129. The dielectric material 134 fills up the opening 129, for example. After that, the second electrode material 136 is formed over the dielectric material 134. In some embodiments, a material of the first electrode material 132 and the second electrode material 136 includes copper (Cu), titanium (Ti), titanium nitride (TiN), tungsten (W), aluminum (Al), tantalum nitride (TaN), combinations thereof, and/or the like. In some embodiments, a material of the dielectric material 134 includes silicon oxide (SiO₂), silicon nitride (Si₃N₄), a high-k dielectric, combinations thereof, and/or the like.

Referring to FIG. 1D, a capacitor 130 is formed by patterning the first electrode material 132, the dielectric material 134 and the second electrode material 136. The patterning process may include a photolithography process and an etching process. For example, portions of the isolation material 131, the first electrode material 132, the dielectric material 134 and the second electrode material 136 are removed using a first mask and then portions of the remained dielectric material 134 and second electrode material 136 are removed using a second mask. Then, the capacitor 130 including an isolation layer 131a, a first electrode layer 132a, a dielectric layer 134a and a second electrode layer 136a is formed. The dielectric layer 134a is disposed between the first electrode layer 132a and the second electrode layer 136a to separate the first electrode layer 132a and the second electrode layer 136a, and the first electrode layer 132a is disposed between the isolation layer 131a and the dielectric layer 134a. The first electrode layer 132a and the dielectric layer 134a may extend into the semiconductor substrate 102 and the interconnect structure 120, and the second electrode layer 136a may be disposed over the semiconductor substrate 102. The capacitor 130 has an MIM structure and may be used to hold a charge indicating a value of one or zero. The capacitor 130 extends into a portion of the semiconductor substrate 102 and a portion of the interconnect structure 120 (e.g., dielectric layers 122). In some embodiments, a first surface (e.g., top surface) 130s1 of the capacitor 130 over the semiconductor substrate 102 is higher than a first surface (e.g., top surface) 110s1 of the electrical circuit 110 (e.g., active device) over the semiconductor substrate 102. A second surface 130s2 (e.g., bottom surface) opposite to the first surface 130s1 of the capacitor 130 in the semiconductor substrate 102 is lower than a second surface 110s2 opposite to the first surface 110s1 of the electrical circuit 110 (e.g., active device) in the semiconductor substrate 102.

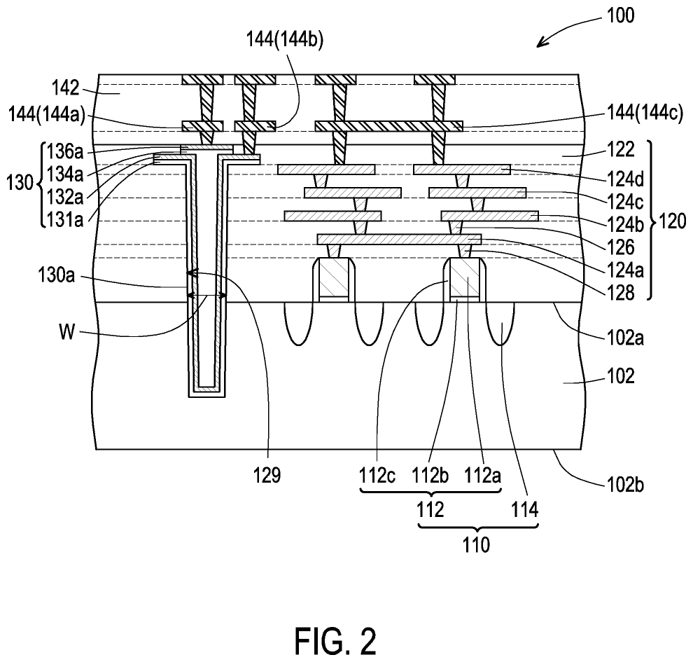

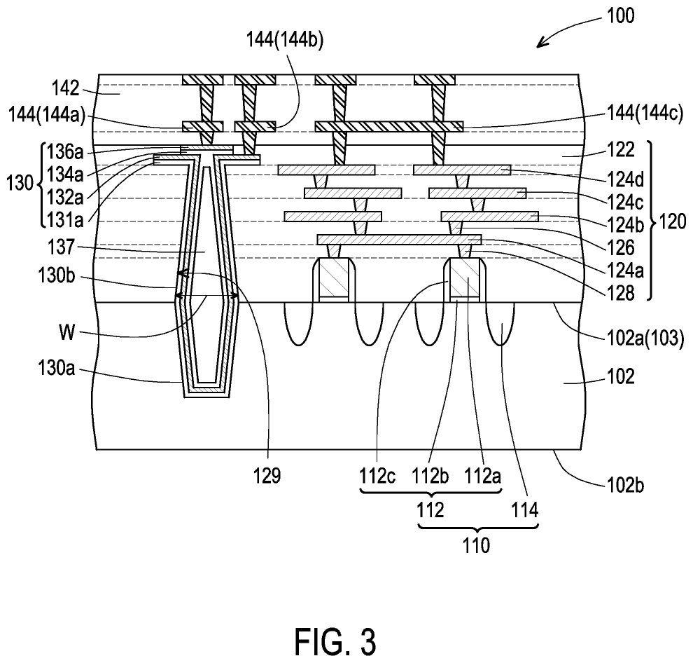

In some embodiments, by using the first and second masks, the first electrode layer 132a and the second electrode layer 136a are respectively exposed. In some embodiments, 131w, 132w sidewalls of the isolation layer 131a and the first electrode layer 132a are substantially flush, and sidewalls 134w, 136w of the dielectric layer 134a and the second electrode layer 136a are substantially flush and inside the sidewalls 131w, 132w of the isolation layer 131a and the first electrode layer 132a. That is, the sidewalls 131w, 132w of the isolation layer 131a and the first electrode layer 132a extend beyond the sidewalls 134w, 136w of the dielectric layer 134a and the second electrode layer 136a, for example. In alternative embodiments, the isolation layer 131a is omitted. In some embodiments, the sidewall 130a of the capacitor 130 is substantially vertical, and a width W of a portion of the capacitor 130 in the opening 129 is substantially constant. However, the disclosure is not limited thereto. In other words, the capacitor 130 may have any suitable profile by adjusting the removal processes of the dielectric layers 122 and the semiconductor substrate 102. In alternative embodiments, as shown in FIG. 2, the sidewall 130a of the capacitor 130 is inclined, and a width W of the capacitor 130 in the opening 129 decreases as the capacitor 130 becomes closer to the second side 102b of the semiconductor substrate 102. In alternative embodiments, as shown in FIG. 3, the capacitor 130 is diamond-like. The capacitor 130 may have a first inclined sidewall 130a in the semiconductor substrate 102 and a second inclined sidewall 130b in the dielectric layers 122. The maximum width W of the capacitor 130 (e.g., maximum width of the opening 129) may be at an interface 103 between the semiconductor substrate 102 and the dielectric layers 122, and the width of the capacitor 130 in the opening 129 may decrease as the capacitor 130 becomes away from the interface 103. In such embodiments, a gap 137 may be formed when the dielectric material 134 is deposited on the first electrode material 132 within the opening 129.

Referring to FIG. 1E, additional dielectric layers 142 are formed over the dielectric layers 122. In some embodiments, the additional dielectric layers 142 include a same material as the dielectric layers 122. In some embodiments, the additional dielectric layers 142 are formed by a deposition process such as CVD, PVD, ALD, combinations thereof, and/or the like. In some embodiments, an etch stop layer (not shown) is formed underneath the dielectric layer 142.

Then, wires 144 are formed in the additional dielectric layers 142. In some embodiments, the wire 144 is formed using multiple etching processes to form openings. The openings are then filled with a conformal barrier material (not shown) and a conformal conductive material (not shown). A planarization process (e.g., a chemical mechanical planarization (CMP) process) is then performed, to remove portions of the conformal barrier material and the conformal conductive material that are above an upper surface of the additional dielectric layers 142. The wire 144 may be formed by using a dual damascene process. The wires 144 may be electrically connected to the interconnect structure 120. In some embodiments, the wire 144a is electrically connected to the first electrode layer 132a of the capacitor 130, and the wire 144b is electrically connected to the second electrode layer 136a of the capacitor 130. The wire 144c is electrically connected to the interconnects 120. In some embodiments, the wire 144c is electrically connected to the gate electrode 112a through the interconnect 124. In alternative embodiments, the wires 144 may also be referred to as routing structure or part of the interconnect structure 120. In other words, the interconnect structure 120 may be partially formed after formation of the capacitor 130.

After formation of the wires 144, a fabrication of an integrated circuit 100 is almost complete. The integrated circuit 100 may be a logic wafer and/or a logic die such as a central processing unit (CPU), a graphics processing unit (GPU), a FPGA, a microcontroller, a system-on-a-chip (SoC), an application-specific integrated circuit (ASIC) device including analog-to-digital converters, data processing circuits, memory circuits, bias circuits, reference circuits, combinations thereof and/or the like. In some embodiments, the integrated circuit 100 includes the capacitor 130 extending into both the semiconductor substrate 102 and the interconnect structure 120 (e.g., dielectric layers 122). In some embodiments, a depth of the capacitor 130 is larger than a depth of the source/drain regions 114. For example, a total height of the capacitor 130 is in a range of 1 m and 10 km. However, the disclosure is not limited thereto. The capacitor 130 may have a depth substantially the same or smaller than the source/drain regions 114. In alternative embodiments, the integrated circuit 100 may include a plurality of capacitors 130 with different depths.

In some embodiments, the capacitor 130 is a three-dimensional (3D) MIM capacitor and extends into both the semiconductor substrate 102 and the dielectric layers 122 of the interconnect structure 120. In other words, the capacitor is formed through front-end-of-line (FEOL) process and back-end-of-line (BEOL) process. In addition, since the capacitor continuously extends into both the substrate and the dielectric layers of the interconnect structure, the capacitor may provide more capacity in a given substrate area.

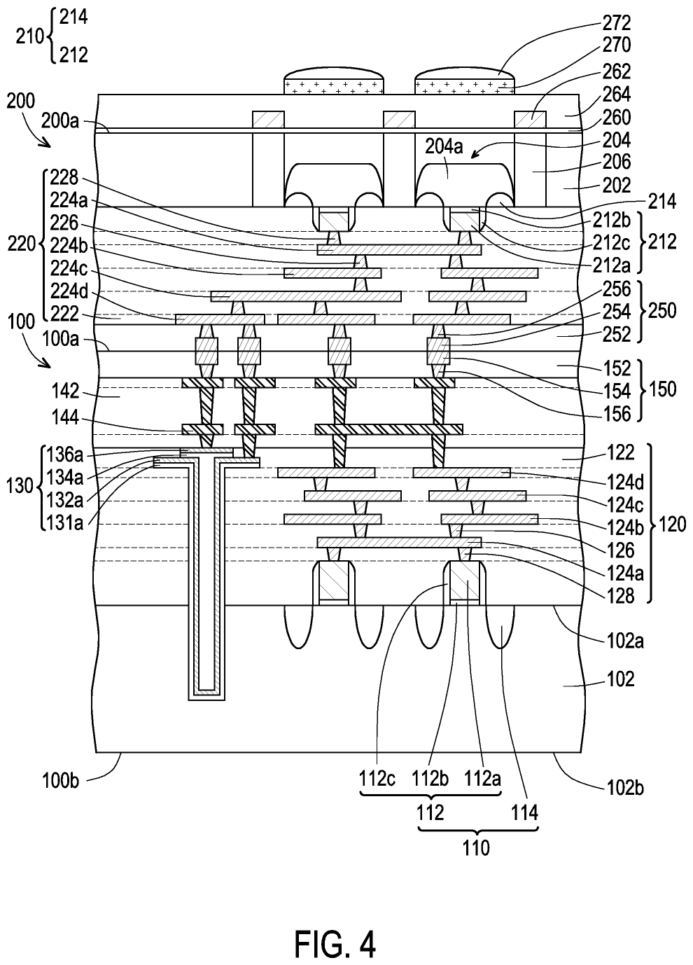

FIG. 4 is a schematic cross-sectional view of a semiconductor device according to some embodiments.

In some embodiments, a semiconductor device includes integrated circuits 100, 200 bonded to each other. The integrated circuit 100 is similar to the integrated circuit 100 of FIG. 1E, and the main difference lies in the integrated circuit 100 of FIG. 4 further includes a bonding structure 150. The bonding structure 150 may be electrically connected to the wires 144 and/or the interconnect structure 120. In some embodiments, the bonding structure 150 includes a bonding layer 152 and a plurality of bonding pads 154 in the bonding layer 152. The bonding structure 150 may further include bonding vias 156 between the bonding pads 154 and the wires 144. The bonding structure 150 may be formed over the additional dielectric layers 142 and the interconnect structure 120. For example, the bonding structure 150 and the semiconductor substrate 102 are disposed at opposite sides of the interconnect structure 120. The bonding layer 152 may include any suitable material for bonding. For example, the bonding layer 152 is a single layer or a multiple layer of silicon oxide, silicon nitride, silicon oxynitride, silicon carbide, silicon oxycarbide, undoped silicon glass, phosphosilicate glass, compounds thereof, composites thereof, combinations thereof, or the like. The bonding layer 152 may be deposited by any suitable method, such as spin-on coating, CVD, PECVD, or the like. A material of the bonding pad 154 includes copper (Cu), titanium (Ti), titanium nitride (TiN), tungsten (W), aluminum (Al), tantalum nitride (TaN), combinations thereof, and/or the like. In some embodiments, the bonding layer 152 may also serve as a passivation layer.

In some embodiments, the integrated circuit 200 is similar to the integrated circuit 100 of FIG. 4. That is, the integrated circuit 200 has similar features as the integrated circuit 100, and for the purpose of the following discussion, the features of the integrated circuit 200 having reference numerals of the form “2xx” are similar to features of the integrated circuit 100 having reference numerals of the form “1xx.” In addition, the disclosure may repeat reference numerals and/or letters in the various examples. This repetition is for the purpose of simplicity and clarity and does not in itself dictate a relationship between the various embodiments and/or configurations discussed.

In some embodiments, the integrated circuit 200 includes a semiconductor substrate 202, electrical circuits 210, an interconnect structure 220, and a bonding structure 250. In some embodiments, the semiconductor substrate 202 of the integrated circuit 200 includes a plurality of pixels 204 and a plurality of isolation structures 206 surrounding the pixels 204. The pixels 204 include radiation-sensing regions 204a. The radiation-sensing regions 204a may be formed by one or more ion implantation processes or diffusion processes and are doped with a doping polarity opposite from that of the semiconductor substrate 202 and thus may also be referred to as radiation-sensing doped regions. In an embodiment, the pixels 204 include n-type doped regions. For a BSI image sensor device, the pixels 204 may be pixel sensors operable to detect radiation, such as an incident light, that is projected toward the semiconductor substrate 202 from a first side (e.g., backside) 200a opposite a second side (e.g., device side). In some embodiments, the pixels 204 each include a photodiode. In alternative embodiments, a deep implant region may be formed adjacent each photodiode. The pixels 204 may also be referred to as radiation-detection devices or light-sensors. In some embodiments, a pitch of the pixels 204 is in a range of 0.5 m and 10 m.

In some embodiments, the isolation structures 206 are shallow trench isolation (STI), deep trench isolation (DTI), or combinations thereof. The isolation structures 206 and the subsequently formed metal grids 262 block light from passing between neighboring pixels 204 to help reduce cross talk. The isolation structures 206 may include a dielectric material, such as silicon oxide, silicon nitride, silicon oxynitride, a low-k dielectric, or any suitable dielectric material. The pixels 204 and the isolation structures 206 may be formed by forming openings in the semiconductor substrate 202 using a drilling process, an etch process, or combinations thereof, filling the openings with the dielectric material, and forming the pixels 204 in the regions between adjacent isolation structures 206. As shown in FIG. 4, the depth of the pixels 204 is generally less than the combined depth of the isolation structures 206. In some embodiments, the pixels 204 are illustrated as having identical junction depths, thicknesses, widths, etc. However, the disclosure is not limited thereto. In alternative embodiments, the pixels 204 may be varied from one another to have different junction depths, thicknesses, widths, etc. Similarly, the isolation structures 206 may be varied from one another to have different junction depths, thicknesses, widths, etc. In some embodiments, the isolation structure 206 may have an inclined sidewall, and a width of the isolation structure 206 may increase as the isolation structure 206 becomes closer to a color filter 270.

The electrical circuits 210 may be adjacent to the pixels 204 for providing an operation environment for the pixels 204 and for supporting external communication with the pixels 204. In some embodiments, the electrical circuits 210 are transistors. For example, the electrical circuit 210 includes a gate structure 212 and source/drain regions 214 at opposite sides of the gate structure 212. In some embodiments, the gate structure 212 includes a gate electrode 212a, a gate dielectric layer 212b and spacers 212c. In some embodiments, the electrical circuits 210 may include various n-type metal-oxide semiconductor (NMOS) and/or p-type metal-oxide semiconductor (PMOS) devices, such as transistors, capacitors, resistors, diodes, fuses, combinations thereof, and/or the like. The electrical circuits 210 may be interconnected to perform one or more functions, which may include memory structures, processing structures, sensors, amplifiers, power distribution, input/output circuitry and/or the like. In an embodiment, the electrical circuits 210 work with the pixels 204 to function as an array of complementary metal oxide semiconductor (CMOS) image sensors (CISs). One of ordinary skill in the art will appreciate that the above examples are provided for illustrative purposes only and are not intended to limit the various embodiments to any particular applications.

The interconnect structure 220 includes a dielectric layer 222 and interconnects 224a, 224b, 224c, 224d (e.g., interconnects 224) therein. The interconnects 224a, 224b, 224c, 224d are electrically connected through conductive features 226. The interconnects 224d are disposed at a level that is away from the electrical circuits 210 and may also be referred to as “Mx”. The interconnects 224c are disposed immediately adjacent the interconnects 224d and may also be referred to as “Mx-1.” The interconnects 224b are disposed immediately adjacent the interconnects 224c and may also be referred to as “Mx-2.” The interconnects 224a are disposed between the interconnects 224b and the first electrical circuits 103 and may also be referred to as “Mx-3.” In some embodiments, the interconnects 224d (“Mx”) are top metallization layers disposed at a highest level in the IMD layers 222 and closest to the integrated circuit 100. In alternative embodiments (not shown), storage devices are disposed between adjacent two of the interconnects 224a, 224b, 224c, 224d. The storage devices may be any suitable capacitors or memory devices, such as metal-insulator-metal (MIM) capacitors or the like, which provide storage capacity for CMOS image sensors. The electrical circuits 210 are in electrical connection with interconnects 224 (e.g., interconnects 224a) through respective conductive via 228 that is disposed between and in contact with an interconnect 224a and a gate electrode 212a of a transistor (e.g., electrical circuits 210). In some embodiments, the conductive feature 226 may have an inclined sidewall, and a width of the conductive feature 226 of the integrated circuit 100 may increase as the conductive feature 226 becomes closer to the integrated circuit 100. Similarly, the conductive feature 126 of the integrated circuit 200 may have an inclined sidewall, and a width of the conductive feature 126 may increase as the conductive feature 126 becomes closer to the integrated circuit 200.

The bonding structure 250 may be electrically connected to the interconnect structure 220 and the electrical circuits 210. In some embodiments, the bonding structure 250 includes a bonding layer 252 and a plurality of bonding pads 254 and bonding vias 256 in the bonding layer 252. The bonding structure 250 may be formed over the interconnect structure 220. In some embodiments, the integrated circuits 100 and 200 are bonded through the bonding structures 150 and 250. For example, the bonding layer 152 is bonded to the bonding layer 252, and the bonding pads 154 are bonded to the bonding pads 254 respectively. In such embodiments, the integrated circuits 100 and 200 are bonded through a hybrid bonding (e.g., dielectric-to-dielectric and metal-to-metal bonding). However, the disclosure is not limited thereto. The integrated circuits 100 and 200 may be bonded through a direct bonding process such as dielectric-to-dielectric bonding (e.g., oxide-to-oxide bonding), metal-to-metal bonding (e.g., copper-to-copper bonding), metal-to-dielectric bonding (e.g., oxide-to-copper bonding), combinations thereof and/or the like.

In some embodiments, the integrated circuits 100 and 200 may include chips and/or dies formed using a CMOS process, a micro-electro-mechanical systems (MEMS) process, or the like. The integrated circuits 100 and 200 may be sensor wafers and/or dies such as a backside illumination sensor (BIS) wafer and/or die, logic wafers and/or dies such as central processing units (CPUs), graphics processing units (GPUs), FPGA, microcontrollers, system-on-a-chips (SoCs), application-specific integrated circuit (ASIC) devices including analog-to-digital converters, data processing circuits, memory circuits, bias circuits, reference circuits, combinations thereof and/or the like. Other logic dies or memory dies (e.g., a DRAM die, a Wide I/O die, a M-RAM die, a R-RAM die, a NAND die, an SRAM die, etc.) may also be used in the integrated circuits 100 and 200. In one exemplary embodiment, the integrated circuit 100 is an ASIC device, and the integrated circuit 200 is a SOC device.

It is noted that the bonding may be at wafer-to-wafer level, wherein the integrated circuits 100 and 200 are bonded together, and are then cut into individual dies. Alternatively, the bonding may be performed at the die-to-die level, or the die-to-wafer level.

In some embodiments, after the integrated circuits 100 and 200 are bonded, a dielectric layer 260 is formed on the first side 200a of the integrated circuit 200. The dielectric layer 260 may include high-k material and may be used as an anti-reflective coating (ARC) to enhance the performance. The high-k material may be an oxide-based material such as SiO₂, Al₂O₃, Ta₂O₅, or the like, and may be formed using any suitable deposition technique such as PVD, ALD, CVD, etc. Then, a plurality of metal grids 262 are disposed in a dielectric layer 264 formed over the dielectric layer 260. The metal grids 262 and the isolation structures 206 block light from passing between neighboring pixels 204 to help reduce cross talk. The metal grids 262 may be formed of tungsten, copper, aluminum copper, or the like.

Then, color filters 270 and micro-lenses 272 are formed over the dielectric layer 264 and between the gaps of the metal grids 262. The integrated circuit 200 is disposed between the integrated circuit 100 and the color filters 270. The color filters 270 are configured such that the incident radiation is directed thereon and therethrough. For example, the color filters 270 are disposed corresponding to the radiation-sensing regions 204a. The color filters 270 may include a dye-based or pigment-based polymer for filtering a specific wavelength band of the incident radiation. The micro-lenses 272 are formed over the color filters 270 and configured to direct and focus the incident radiation toward the radiation-sensing regions 204a in the semiconductor substrate 202, such as pixels 204. The micro-lenses 272 may have various shapes depending on a refractive index of a material used for the micro-lenses 272 and distance from a sensor surface.

In some embodiments, the integrated circuits 100 and 200 are stacked to form 3D stacked CMOS image sensors, and the capacitor 130 of the integrated circuit 100 provides storage capacity for CMOS image sensors. The capacitor 130 extends into the semiconductor substrate 102 of the integrated circuit 100 and the at least one dielectric layer 122 between the semiconductor substrate 102 of the integrated circuit 100 and the semiconductor substrate 202 of the integrated circuit 200. In some embodiments, the capacitor 130 is formed through both front-end-of-line (FEOL) process and back-end-of-line (BEOL) process. Thus, the capacitor may gain more capacity. In some embodiments in which the pixel size is shrunk, the capacitor may maintain a good capacity value compared to the capacitor without extending into the interconnect structure. In other words, the capacitor provides more capacity in a given substrate area. Thus, the performance of the CMOS image sensors may be improved.

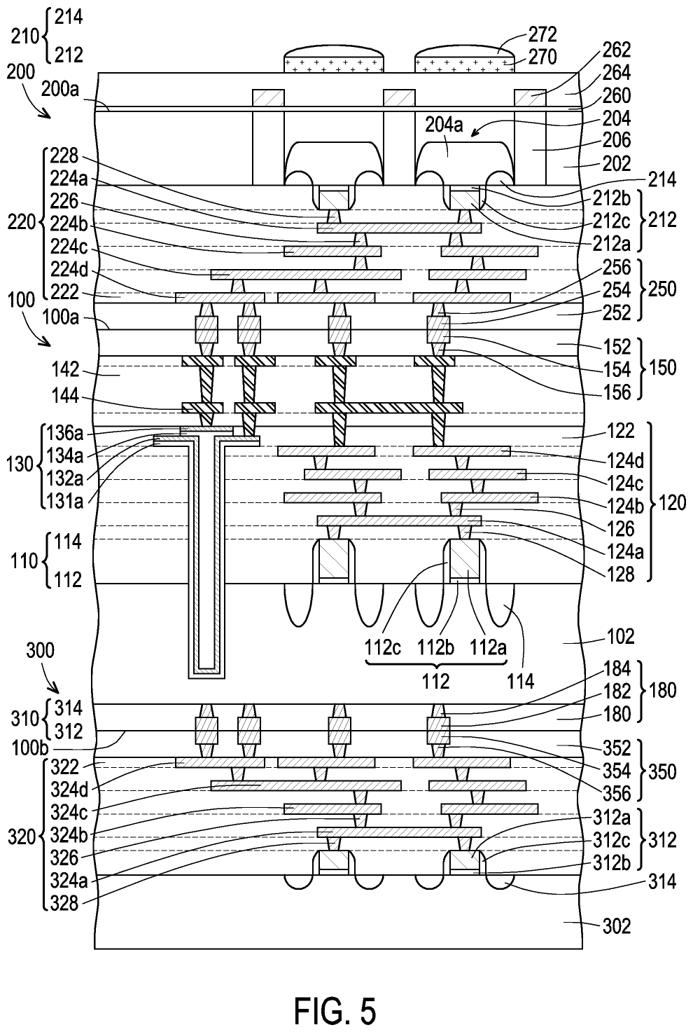

In some embodiments, the semiconductor device includes bonded integrated circuits 100, 200. However, the disclosure is not limited thereto. In alternative embodiments, as shown in FIG. 5, the semiconductor device may further include an integrated circuit 300, and the integrated circuits 200 and 300 are disposed at opposite sides of the integrated circuit 100. For example, the integrated circuit 200 is disposed at a first side 100a of the integrated circuit 100, and the integrated circuit 300 is disposed at a second side 100b opposite to the first side 100a of the integrated circuit 100. The integrated circuit 300 may be formed bonded to the integrated circuit 100. The integrated circuit 300 has similar features as the integrated circuits 100, 200, and for the purpose of the following discussion, the features of the integrated circuit 300 having reference numerals of the form “3xx” are similar to features of the integrated circuit 100, 200 having reference numerals of the form “1xx” and “2xx.” Various elements of the integrated circuit 300 will be referred to as the “third <element>3xx.” It is understood that while the integrated circuit 300 is shown to be bonded to the integrated circuit 100, the integrated circuit 300 may also be bonded to the backside of the integrated circuit 200.

In some embodiments, the integrated circuit 300 includes a semiconductor substrate 302, electrical circuits 310, an interconnect structure 320, and a bonding structure 350. The interconnect structure 320 includes a dielectric layer 322 and interconnects 324a, 324b, 324c, 324d (e.g., interconnects 324) therein.

In some embodiments, the integrated circuit 300 and the integrated circuits 100 and 200 are arranged with a front side of a semiconductor substrate 302 facing the second side 100b of the semiconductor substrate 102. Before the bonding, a bonding structure 180 may be formed over the second side 100b of the semiconductor substrate 102. The bonding structure 180 may be similar to the bonding structure 150 and may include a bonding layer 182 and a plurality of bonding pads 184 and a plurality of bonding vias 186 in the bonding layer 182. The bonding structure 180 is electrically connected to the interconnect structure 120 and/or the electrical circuits 110, for example. The integrated circuit 300 may be bonded to the integrated circuit 100 using a hybrid bonding technology, e.g., by bonding a bonding structure 350 (having features similar to the bonding structure 150) of the integrated circuit 300 to the bonding structure 150 of the integrated circuit 100. In such embodiments, bonding pads 354 are directly bonded to the bonding pads 184, and a bonding layer 352 of the integrated circuit 300 is directly bonded to the bonding layer 182 of the integrated circuit 100. The bonding structure 350 may further include bonding vias 356. The bonding structure 150 and the bonding structure 350 thus form a hybrid bonding structure, allowing for power and electrical/photodiode signals from the integrated circuit 200 (e.g., hole structure on outermost surface of the integrated circuit 200) to be distributed to various elements in the integrated circuits 100 and 200. In some embodiments, the integrated circuit 300 is bonded to the integrated circuit 100 after the integrated circuits 100 and 200 are bonded. However, the disclosure is not limited thereto. The integrated circuit 300 may be bonded to the integrated circuit 100 before the integrated circuits 100 and 200 are bonded. In some embodiments, the dielectric layer 260, the metal grids 262, the dielectric layer 264, the color filters 270 and the micro-lenses 272 may be formed after the integrated circuit 300 and the integrated circuits 100 and 200 are bonded.

The integrated circuit 300 may be a wafer and/or die formed using a CMOS process, a MEMS process, or the like. The integrated circuit 300 may be a logic wafer and/or a die such as an SOC device, an ASIC device including analog-to-digital converters, data processing circuits, memory circuits, bias circuits, reference circuits, combinations thereof and/or the like. Other logic die (e.g., central processing unit, FPGA, microcontroller, etc.) or memory die (e.g., a DRAM die, a Wide I/O die, a M-RAM die, a R-RAM die, a NAND die, an SRAM die, etc.) may also be used in the integrated circuit 300. In one exemplary embodiment, the integrated circuit 300 is an ASIC device. In some embodiments, the capacitor 130 is formed in one of the integrated circuits 100, 200 and 300 (e.g., integrated circuit 100). In alternative embodiments, more than one integrated circuit (e.g., integrated circuit 200 and/or the integrated circuit 300) may also include capacitors having similar structure as the capacitor 130.

In some embodiments, the integrated circuits 100, 200 and 300 are stacked to form 3D stacked CMOS image sensors, and the capacitor 130 of the integrated circuit 100 provides storage capacity for CMOS image sensors. In some embodiments, the capacitor 130 is formed through both front-end-of-line (FEOL) process and back-end-of-line (BEOL) process. Thus, the capacitor may gain more capacity. In some embodiments in which the pixel size is shrunk, the capacitor may maintain a good capacity value compared to the capacitor without extending into the interconnect structure. In other words, the capacitor provides more capacity in a given substrate area. Thus, the performance of the CMOS image sensors may be improved.

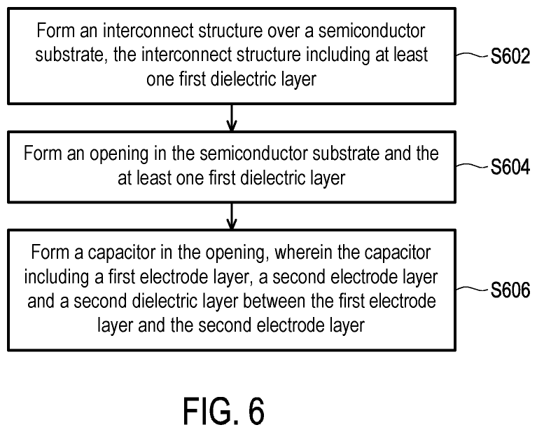

FIG. 6 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S602, an interconnect structure is formed over a semiconductor substrate, and the interconnect structure includes at least one first dielectric layer. FIG. 1A illustrates a view corresponding to some embodiments of act S602.

At act S604, an opening is formed in the semiconductor substrate and the at least one first dielectric layer. FIG. 1B illustrates a view corresponding to some embodiments of act S604.

At act S606, a capacitor is formed in the opening, wherein the capacitor includes a first electrode layer, a second electrode layer and a second dielectric layer between the first electrode layer and the second electrode layer. FIG. 1C to FIG. 1E and FIG. 2 to FIG. 5 illustrate views corresponding to some embodiments of act S606.

According to some embodiments, a semiconductor device includes an integrated circuit. The integrated circuit includes a semiconductor substrate, an active device, an interconnect structure and a capacitor. The capacitor extends into the semiconductor substrate and the interconnect structure.

According to some embodiments, a semiconductor device includes a first integrated circuit and a second integrated circuit. The first integrated circuit includes a first semiconductor substrate, at least one dielectric layer and capacitor. The second integrated circuit is bonded to the first integrated circuit. The second integrated circuit includes a second semiconductor substrate. The capacitor extends into the first semiconductor substrate and the at least one dielectric layer between the first semiconductor substrate and the second semiconductor substrate.

According to some embodiments, a method of forming a semiconductor device includes following steps. An interconnect structure is formed over a semiconductor substrate. The interconnect structure includes at least one first dielectric layer. An opening is formed in the semiconductor substrate and the at least one first dielectric layer. A capacitor is formed in the opening. The capacitor includes a first electrode layer, a second electrode layer and a second dielectric layer between the first electrode layer and the second electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an integrated circuit, comprising a semiconductor substrate, an active device, an interconnect structure and a capacitor, wherein the capacitor extends into the semiconductor substrate and the interconnect structure.

2. The semiconductor device of claim 1, wherein the capacitor comprises a first electrode layer, a second electrode layer and a dielectric layer between the first electrode layer and the second electrode layer.

3. The semiconductor device of claim 2, wherein the first electrode layer and the dielectric layer extend into the semiconductor substrate and the interconnect structure, and the second electrode layer is disposed over the semiconductor substrate.

4. The semiconductor device of claim 2, wherein a sidewall of the first dielectric layer is substantially flush with a sidewall of the second electrode layer.

5. The semiconductor device of claim 2, wherein a sidewall of the first electrode layer extends beyond a sidewall of the second electrode layer.

6. The semiconductor device of claim 2 further comprising a first wire electrically connected to the first electrode layer, and a second wire electrically connected to the second electrode layer.

7. The semiconductor device of claim 2, wherein a first surface of the capacitor over the semiconductor substrate is higher than a first surface of the active device over the semiconductor substrate.

8. The semiconductor device of claim 7, wherein a second surface opposite to the first surface of the capacitor in the semiconductor substrate is lower than a second surface opposite to the first surface of the active device in the semiconductor substrate.

9. The semiconductor device of claim 2, wherein the capacitor further comprises an isolation layer between the first electrode layer and the semiconductor substrate.

10. The semiconductor device of claim 9, wherein a sidewall of the first electrode layer is substantially flush with a sidewall of the isolation layer.

11. A semiconductor device, comprising:
a first integrated circuit, comprising a first semiconductor substrate, at least one dielectric layer and capacitor; and
a second integrated circuit bonded to the first integrated circuit, comprising a second semiconductor substrate, wherein the capacitor extends into the first semiconductor substrate and the at least one dielectric layer between the first semiconductor substrate and the second semiconductor substrate.

12. The semiconductor device of claim 11, wherein the first integrated circuit further comprises a first bonding layer, and the second integrated circuit further comprises a second bonding layer bonded to the first bonding layer.

13. The semiconductor device of claim 11, wherein the first integrated circuit further comprises a plurality of first bonding pads, and the second integrated circuit further comprises a plurality of second bonding pads bonded to the first bonding pads respectively.

14. The semiconductor device of claim 11, wherein the second integrated circuit comprises a plurality of radiation-sensing regions in the second semiconductor substrate.

15. The semiconductor device of claim 14 further comprising a plurality of color filters disposed corresponding to the radiation-sensing regions, wherein the second integrated circuit is disposed between the first integrated circuit and the color filters.

16. A method of forming a semiconductor device, comprising:
forming an interconnect structure over a semiconductor substrate, the interconnect structure comprising at least one first dielectric layer;
forming an opening in the semiconductor substrate and the at least one first dielectric layer; and
forming a capacitor in the opening, wherein the capacitor comprises a first electrode layer, a second electrode layer and a second dielectric layer between the first electrode layer and the second electrode layer.

17. The method of claim 16, wherein forming the capacitor comprises:
forming a first electrode material on exposed surfaces of the opening and the at least one first dielectric layer;
forming a dielectric material on the first electrode material in the opening;
forming a second electrode material on the dielectric material; and
removing portions of the first electrode material, the dielectric material and the second electrode material.

18. The method of claim 17, wherein removing the portions of the first electrode material, the dielectric material and the second electrode material comprises:
removing first portions of the first electrode material, the dielectric material and the second electrode material; and
removing second portions of the dielectric material and the second electrode material.

19. The method of claim 18, wherein a sidewall of the first electrode layer extends beyond a sidewall of the second electrode layer.

20. The method of claim 18, wherein a sidewall of the second electrode layer is substantially flush with a sidewall of the second electrode layer.
